(19) United States
(12) Patent Application Publication
(10) Pub. No.: US 2026/0324170 A1
(43) Pub. Date: Oct. 15, 2026

(54) Local Crosstalk Increase for Micro LED Defect Pixel Compensation

(71) Applicant: Apple Inc., Cupertino, CA (US)

(72) Inventors: Lixia Zhou, Sunnyvale, CA (US); Rong Liu, Cupertino, CA (US); Yifei Zhang, San Mateo, CA (US); Tore Nauta, Santa Cruz, CA (US); Joshua A. Spechler, Campbell, CA (US); Jun Qi, San Jose, CA (US); Mingjing Ha, Cupertino, CA (US); Elmar Gehlen, San Jose, CA (US)

(21) Appl. No.: 19/454,035

(22) Filed: Jan. 20, 2026

Related U.S. Application Data
(60) Provisional application No. 63/785,940, filed on Apr. 9, 2025.

(51) Int. Cl. H10H 29/855; H10H 29/01

(52) U.S. Cl. CPC H10H 29/855; H10H 29/0363

(57) ABSTRACT

Optoelectronic structures and methods of fabrication are described in which an array of micro LEDs is arranged in the array of pixels that includes a defective pixel. An array of optical elements is formed over the array of micro LEDs, where the array of optical elements includes a modified optical element with a local perturbation over the defective pixel, while all other optical elements of the array of optical elements have a common shape. In this manner the local perturbation may facilitate optical crosstalk for compensation of the defective pixel.

### RELATED APPLICATIONS

This application claims the benefit of priority of U.S. Provisional Application No. 63/785,940, filed Apr. 09, 2025, which is incorporated herein by reference.

### BACKGROUND

### Field

Embodiments described herein relate to optoelectronic structures, and more particularly to micro light emitting diode projectors.

### Background Information

Augmented reality display systems commonly operate by projecting a virtual image to a user’s eye while viewing real world images. One manner for achieving this is with optical waveguide technology where the virtual image can be injected into a waveguide from a source display, or projector, and then extracted in front of the eye where the image can be superimposed with the real-world vision. One attractive feature of such optical waveguide technology is the ability to provide a high field-of-view at low form factors.

Due to the small form factors of such systems, the projectors may be fabricated using arrays of micro light emitting diodes (LEDs), with maximum widths of the order of tens of microns or less. Such miniaturized size of the light source can lead to visible pixel defects from a variety of sources ranging from the micro LED growth wafers to micro LED functionalization and integration into the projectors.

### SUMMARY

Optoelectronic structures and methods of fabrication are described. In an embodiment, an optoelectronic structure includes an array of pixels, an array of micro LEDs arranged in the array of pixels, an array of optical elements over the array of micro LEDs. The array of pixels in accordance with embodiments includes a defective pixel, and the array of optical elements includes a modified optical element including a local perturbation over the defective pixel, while all other optical elements of the array of optical elements have a common shape. The local perturbations can be formed using subtractive or additive processing techniques. In an embodiment, the array of optical elements includes an array of lenses, and the modified optical element includes a modified lens. For example, the local perturbation can include a roughened surface or indentation in the modified lens. The indentation can assume a variety of shapes including cone-shaped, and being characterized by a radius. In another embodiment, the local perturbation is formed by an additive technique and includes a surface layer formed on top of a lens. The local perturbation can also include a diffuser layer that includes a dispersion of scattering particles or voids.

The array of micro LEDs can be integrated into the optoelectronic structure with a variety of suitable manners including surface mounting individual micro LEDs and the integration of one or more coupons. In an embodiment, the array of micro LEDs is contained within a coupon that is embedded in a planarization layer. In an embodiment the coupon is connected with a silicon backplane. The array of lenses may also be formed of a continuous material layer that spans over the coupon and the planarization layer. Furthermore, a cover glass can span over the array of lenses in the integrated structure.

In an embodiment a method of forming an optical structure includes applying an optically transparent layer over an array of micro LEDs arranged in an array of pixels, and patterning the optically transparent layer to form an array of optical elements over the array of micro LEDs, the array of optical elements including a local perturbation over a defective pixel. In an embodiment patterning the optically transparent layer to form the array of optical elements includes patterning the optically transparent layer to form an array of lenses over the array of micro LEDs, with each of the lenses of the array of lenses having a common shape. In some embodiments the method of formation includes modifying a lens to include a local perturbation over the defective pixel, such as by focusing a laser on the lens to roughen a surface of the lens or forming an indentation in the lens. In some embodiments the method of formation includes depositing a surface layer on top of a lens to form the local perturbation or depositing a diffuser layer over the defective pixel to form the local perturbation. In some embodiments the method of formation includes embedding a coupon in a planarization layer, where the array of micro LEDs is contained within the coupon, and applying the optically transparent layer over an array of micro LEDs includes applying the optically transparent layer over the coupon and the planarization layer.

### BRIEF DESCRIPTION OF THE DRAWINGS

FIG. 1 is a schematic cross-sectional side view illustration of an optoelectronic structure in accordance with an embodiment.

FIG. 2 is a schematic top view illustration of an optoelectronic structure with a defective pixel in accordance with an embodiment.

FIG. 3 is a close-up schematic cross-sectional side view illustration of an optoelectronic structure in accordance with an embodiment.

FIG. 4 is a schematic cross-sectional side view illustration of an array of optical elements with common shape formed over an array of micro LEDs including a micro LED within a defective pixel in accordance with an embodiment.

FIG. 5 is a schematic cross-sectional side view illustration of a modified optical element with a roughened surface over a micro LED within a defective pixel in accordance with an embodiment.

FIG. 6A is a schematic cross-sectional side view illustration of a modified optical element with a patterned surface over a micro LED within a defective pixel in accordance with an embodiment.

FIG. 6B is a schematic top view illustration of a modified optical element with a patterned surface in accordance with an embodiment.

FIG. 7A is a schematic cross-sectional side view illustration of a modified optical element with a deposited layer over a micro LED within a defective pixel in accordance with an embodiment.

FIG. 7B is a schematic cross-sectional side view illustration of a modified optical element with added micro structures over a micro LED within a defective pixel in accordance with an embodiment.

FIG. 7C is a schematic top view illustration of a modified optical element with added micro structures in accordance with an embodiment.

FIG. 8 is a schematic cross-sectional side view illustration of a modified optical element with a cone-shaped indentation over a micro LED within a defective pixel in accordance with an embodiment.

FIG. 9A is a schematic cross-sectional side view illustration of a modified optical element with an indentation over a micro LED within a defective pixel in accordance with an embodiment.

FIG. 9B is a schematic top view illustration of a modified optical element with an indentation in accordance with an embodiment.

FIG. 10 is a schematic cross-sectional side view illustration of a modified optical element with a roughened surface over a micro LED within a defective pixel in accordance with an embodiment.

FIG. 11 is a schematic cross-sectional side view illustration of a modified optical element with a diffuser layer over a micro LED within a defective pixel in accordance with an embodiment.

### DETAILED DESCRIPTION

Embodiments describe optoelectronic structures and methods of fabrication in which the optical elements over defective pixels are selectively modified in order to increase optical crosstalk for pixel compensation.

In one aspect, it has been observed that micro LED projectors can have a brightness non-uniformity due to dim micro LED pixels due to variety of factors such as a defective LED, compromised electrical contact or pixel driving circuit, etc. One solution for achieving a more uniform brightness can be to increase operating current of neighboring micro LED pixels, and therefore local brightness, adjacent to a defect site in order to smear the overall brightness with local optical crosstalk. However, this comes at a cost of increased power overhead. In accordance with embodiments, localized crosstalk is promoted over identified defective pixel sites by instead modifying the optics over the identified defective pixels to facilitate optical crosstalk over the defective pixels, without necessarily modifying the operation or optics of the adjacent good micro LED pixels. This can be achieved by introducing local perturbations in the optical elements over the defective pixels with either subtractive or additive approaches.

In another aspect, embodiments describe optoelectronic structures and methods of fabrication in which high densities of micro LEDs can be bonded to a substrate, such as a complementary metal–oxide–semiconductor (CMOS) substrate or substrate including an array of pixel driver chips, at high pixel densities and landing pad pitch. For example, embodiments may be utilized to fabricate projectors with pixel densities greater than 5,000 ppi and backplane landing pad pitch of 5 µm or less. This can be achieved using a reconstitution process in which coupons of micro LED arrays from growth substrates are transferred to a carrier wafer and reconstituted to form via contacts as part of a reconstituted wiring layer, followed by wafer-to-wafer bonding to a CMOS substrate (or substrate including an array of pixel driver chips), and final singulation of the optoelectronic structures.

As used herein the term “micro LEDs” may refer to the maximum lateral dimension of the device. In some embodiments, the “micro” sized diodes may have a maximum lateral dimension below 100 µm, such as below 10 µm, such as 5 µm, 0.5 µm, or less. In a specific embodiment, the micro LEDs have a maximum lateral dimension of 1 µm. The processing sequences in accordance with embodiments may be used to form both monochromatic and full color optoelectronic structures.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

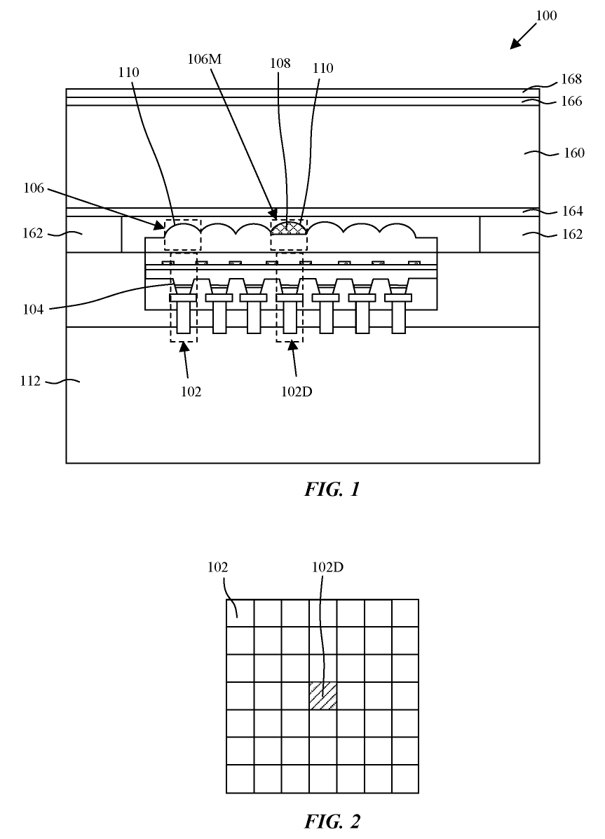

Referring now to FIG. 1, a cross-sectional side view illustration is provided of an optoelectronic structure 100 including an array of pixels 102 and an array of micro LEDs 104 arranged in the array of pixels. In accordance with embodiments, the array of pixels 102 additionally includes a defective pixel 102D, which can be caused by a variety of factors including a defective LED, electrical contact with the LED, driving circuitry, etc. FIG. 2 is a schematic top view illustration of a defective pixel 102D within the array of pixels 102. Referring again to FIG. 1, an array of optical elements 106 is oriented over the array of micro LEDs 104, where the array of optical elements 106 includes a modified optical element 106M including a local perturbation 108 over the defective pixel 102D while all other optical elements of the array of optical elements have a common shape. In the particular embodiment illustrated the optical elements 106 are half-ball shaped lenses 110, though other lenses 110 and shapes (e.g., conical, trapezoidal, columnar, etc.) are possible.

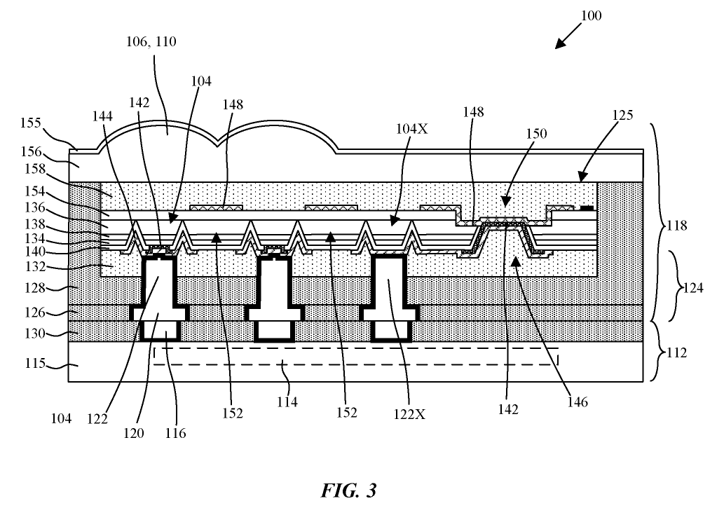

FIG. 3 is a close-up schematic cross-sectional side view illustration of an optoelectronic structure 100 of FIG. 1 in accordance with an embodiment. In interest of clarity and conciseness, FIGS. 1 and 3 are discussed concurrently. In an embodiment, an optoelectronic structure 100 includes a backplane 112 including driving circuitry 114 (e.g. CMOS driving circuitry in a semiconductor substrate 115 (silicon backplane) or pixel driver chip(s) embedded in a display substrate 115) and an array of contact pads 116, and a device layer 118 bonded to the backplane 112. The device layer 118 may have been formed as part of a reconstitution process and include an array of micro LEDs 104, an array of landing pads 120 underneath the array of micro LEDs 104 and an array of via contacts 122 connected to the array of landing pads 120, where each via contact 122 corresponds to a landing pad 120. In accordance with embodiments, the array of landing pads 120 is part of a reconstituted wiring layer 124 that is directly bonded with the array of contact pads 116 with metal-metal bonds (e.g. copper-copper).

The array of via contacts 122 may be formed with a damascene process, including single damascene, double damascene. The array of via contacts 122 may be formed as part of a single metal layer or multiple metal layers within the reconstituted wiring layer 124 for routing distribution. In the particular embodiment illustrated a single damascene and single metal layer is shown, though embodiments are not so limited. The array of via contacts 122 may also be embedded within a dielectric build-up layer 126. For example, this may be a part of the planarization layer 128 or a separate layer formed on top of the planarization layer 128 and coupons 125 during the reconstitution sequence. As shown, the dielectric build-up layer 126 can be bonded directly to a top dielectric layer 130 of the backplane 112 with dielectric-dielectric bonds (e.g. oxide-oxide, etc.).

In accordance with embodiments, the array of micro LEDs 104 may be part of one or more coupons 125. For example, the coupons 125 may include a p-n diode layer that is patterned into an array of micro LEDs 104. Each micro LED 104 may include a bottom doped layer 134 (e.g. p-doped), a top doped layer 136 (e.g. n-doped) with an opposite doping than the bottom doped layer, and optionally an active layer 138 between the bottom doped layer and the top doped layer. For example, the active layer 138 may include one or more quantum well layers and barrier layers separating the quantum well layers.

The micro LEDs 104 may be designed for emission of primary red light (e.g. 600-700 nm wavelength), primary green light (e.g. 495–570 nm wavelength), or primary blue light (e.g. 450–495 nm wavelength), though embodiments are not limited to these exemplary emission spectra. The micro LEDs 104 may be formed of a variety of compound semiconductors having a bandgap corresponding to a specific region in the spectrum. For example, the micro LEDs 104 can include one or more layers based on II-VI materials (e.g. ZnSe) or III-V materials including III-V nitride materials (e.g. GaN, AlN, InN, InGaN, and their alloys), III-V phosphide materials (e.g. GaP, AlGaInP, and their alloys), and III-V arsenide alloys (AlGaAs).

By way of example, in an embodiment the micro LEDs 104 are designed for emission of red light, and the materials are phosphorus based. The following listing of materials for red emission is intended to be exemplary and not limiting. For example, the layers forming the p-n diode layers may include AlInP, AlInGaP, AlGaAs, GaP, and GaAs.

By way of example, in an embodiment, the micro LEDs 104 are designed for emission of blue or green light, and the materials are nitride based. The following listing of materials for blue or green emission is intended to be exemplary and not limiting. For example, the layers forming the p-n diode layers may include GaN, AlGaN, InGaN.

A dielectric insulation layer 140 may be formed over, along sidewalls and between the micro LEDs 104 to provide electrical insulation. An opening may be formed in the dielectric insulation layer 140 on the bottom side of the bottom doped layer 134 to allow a bottom electrical contact 142 to make electrical contact with the bottom doped layer 134 (or some intervening current spreading layer). The bottom electrical contact 142 may be a single layer, or multiple metal layer stack for example. A reflector layer 144 may optionally be formed on the dielectric insulation layer 140, and optionally the bottom electrical contact 142. The optional reflector layer 144 may be formed of a suitable material (e.g. Au, Ag, Al, Ru, etc.) to reflect a peak emission/absorption wavelength of the micro LED 104. In the illustrated embodiments, via contacts 122 are formed directly on the reflector layer 144, though intervening contact pads can also be formed. A backside dielectric fill layer 132 may be located over the back sides of the micro LEDs 104. The backside dielectric fill layer 132 may be formed of a suitable material such as BCB and may be transparent or opaque.

Furthermore, a planarization layer 128 may laterally surround each coupon 125 and be located laterally between adjacent coupons during the reconstitution process. Each coupon 125 may include a backside dielectric fill layer 132. In this manner, the array of via contacts 122 extend through a corresponding backside dielectric fill layer 132. In an embodiment a pitch between the via contacts 122 within each sub-array of via contacts is 5 µm or less, though embodiments are not so limited.

Referring FIG. 3, a supplemental via contact 122X is illustrated that can provide electrical connection between the working circuitry 114 of the backplane 112 and the top sides of the micro LEDs 104. As shown, the via contact 122X can optionally land on a reflector layer 144 when present, or even one of the layers used to form the reflector layers 144 for a spare micro LED 104X or an intermediate p-n diode layer material 152. The reflector layer 144 or other metal layer such as bottom electrical contact 142 may run through an opening 146 in and underside of the p-n diode layer and make contact with an electrically conductive top electrode layer 148 on a top side of the p-n diode layer. The top electrode layer 148 may optionally be formed within an opening 150 in the top side of the p-n diode layer. Exemplary materials for top electrode layer 148 include metallic materials such as Ni, Ge, Al, Pt, Ru, Au, including metal stack-up combinations thereof, and alloys thereof. As such, the top electrode layer 148 may be opaque. As shown in FIG. 3, the top electrode layer 148 may be patterned into a mesh, or grid, configuration with openings over each micro LED 104. In this way, the metallic materials forming the top electrode layer 148 are located above the intermediate p-n diode layer material 152 and do not absorb significant light emitted by the functional micro LEDs 104. Electrical connection can be facilitated by a doped current spreading layer 154 (e.g. n++ doped III-V material) within the p-n diode layer. The top contact layer 154 and top electrode layer 148 of the coupons 125 may be covered with a protective dielectric layer 158, which may also be transparent.

In accordance with embodiments, optical structures such as micro lens array can then be formed over the encapsulated coupons 125 of micro LEDs 104. For example, an optical layer 156 such as a transparent polymer or inorganic material (e.g., silicon nitride, oxide) can be a continuous material layer deposited over the encapsulated coupons 125 and planarization layer 128, followed by patterning to form an array of optical elements 106 in the continuous material layer. Patterning can be achieved using suitable techniques such as lithography, imprint lithography, embossing, etc. In the particular embodiment illustrated the optical elements 106 are half-ball shaped lenses 110, though other lenses 110 and shapes (e.g., conical, trapezoidal, columnar, etc.) are possible. A capping layer 155 can optionally be formed over the patterned optical layer 156. The capping layer 155 may also be transparent and provide additional functionality such as antireflection and/or passivation. Referring back to FIG. 1, where a defective pixel 102D is identified, a modified optical element 106M including a local perturbation 108 can be formed prior to attachment of a cover glass 160. For example, cover glass 160 may be an optically transparent glass, polymer, sapphire, etc. and be attached with an adhesive material 162 outside of the optical area. Various anti-reflective coatings 164, 166 may be formed on the top and/or bottom sides of the cover glass 160. An anti-scratch coating 168 may be formed as a topmost layer. An array of optoelectronic structures 100 can be singulated from a single wafer stack at this point.

In accordance with embodiments, a method of forming an optical structure 100 can include applying an optically transparent layer 156 over an array of micro LEDs 104 arranged in an array of pixels 102, and patterning the optically transparent layer to form an array of optical elements 106 over the array of micro LEDs 104. For example, patterning the optically transparent layer to form the array of optical elements includes patterning the optically transparent layer to form an array of lenses 110 over the array of micro LEDs 104, with each of the lenses 110 having a common shape. In accordance with embodiments, the array of optical elements 106 additionally includes a local perturbation 108 over a defective pixel 102D. For example, a lens 110 can be modified to include a local perturbation 108 over a defective pixel 102D to facilitate local optical crosstalk and light extraction over the defective pixel 102D. Alternatively, a local perturbation 108 can be formed over the lens 110.

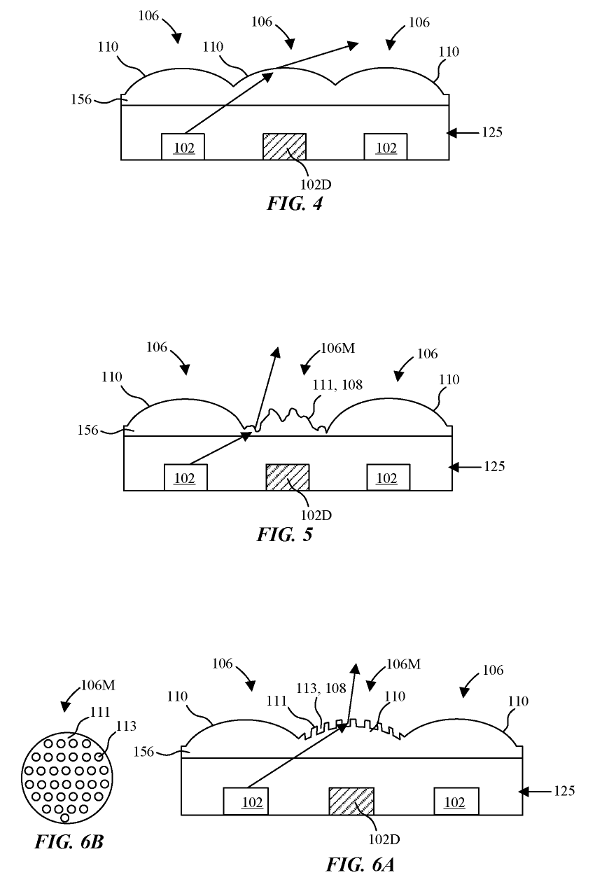

FIG. 4 is a schematic cross-sectional side view illustration of an array of optical elements 106 with common shape formed over an array of micro LEDs including a micro LED within a defective pixel 102D in accordance with an embodiment. As shown, the optical elements 106, in the shape of half-ball lenses 110, can be designed for light extraction from LEDs within their corresponding pixels 102, though not for adjacent pixels. As shown, light emitted from a micro LED 104 of an adjacent pixel 102 is not preferentially extracted by the optical element 106 of the defective pixel 102D.

FIG. 5 is a schematic cross-sectional side view illustration of a modified optical element 106M in which the perturbation 108 is a roughened surface over a micro LED within a defective pixel 102D in accordance with an embodiment. For example, the roughened surface can be formed by a subtractive technique such as laser (e.g. ultraviolet) patterning, dry etching, etc. or patterning a hardmask used for lens 110 formation so that the pattern is transferred directly to the lens 110. For example, a photoresist layer can be patterned to form islands, which are then reflowed to form domes that can be further patterned to include a roughened or patterned surface. This roughened or patterned surface can then be transferred to the lenses 110 formed in the optical layer upon etching of the photoresist layer (hardmask).

FIG. 6A is a schematic cross-sectional side view illustration of a modified optical element 106M in which the perturbation 108 is a patterned surface over a micro LED within a defective pixel 102D in accordance with an embodiment. FIG. 6B is a schematic top view illustration of a modified optical element 106M with a patterned surface in accordance with an embodiment. FIGS. 6A and 6B can be substantially similar to that of FIG. 5, with a difference being that the surface 111 is patterned to facilitate diffraction. For example, this may be accomplished by patterning an array of holes 113 into the surface 111 of the lens 110 in the modified optical element 106M. In an embodiment, the holes 113 have an aspect ratio of about 1 (width to depth). In an embodiment, the holes 113 have a uniform diameter, and uniform pitch. In an exemplary embodiment, the holes have a diameter of approximately 250 nm and pitch of approximately 300 nm.

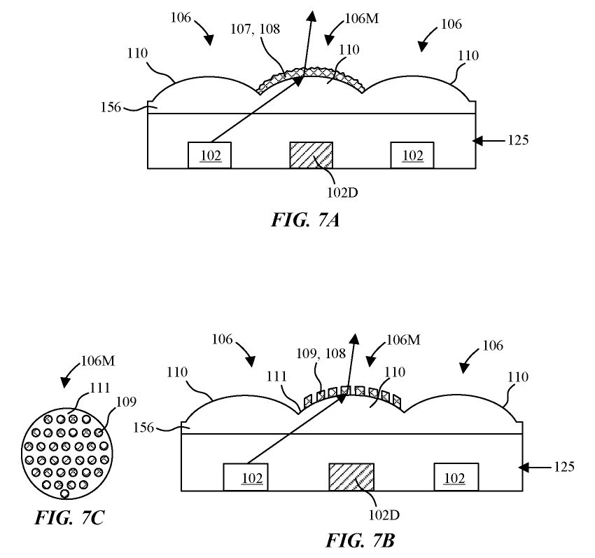

FIG. 7A is a schematic cross-sectional side view illustration of a modified optical element 106M in which the perturbation 108 is a deposited material layer 107 over a micro LED within a defective pixel 102D in accordance with an embodiment. For example, the material layer may be deposited using a suitable technique such as 2-photon polymerization (TPP), allowing for the creation of complex features. The material layer 107 may be formed of a material with different refractive index than the optical layer 156, and may optionally have a higher average surface roughness (Ra). The material layer 107 may be a continuous layer substantially covering the underlying lens 110.

FIG. 7B is a schematic cross-sectional side view illustration of a modified optical element with added micro structures 109 over a micro LED within a defective pixel in accordance with an embodiment. FIG. 7C is a schematic top view illustration of a modified optical element with added micro structures 109 in accordance with an embodiment. The topography of the modified optical element 106M may be similar to that of FIGS. 6A-6B, though formed through an additive technique such as TPP of FIG. 7A rather than a subtractive technique. Thus, the added micro structures can be formed on the surface 111 of the underlying lens 110. The micro structures 109 can have refractive and/or diffractive functions and may be formed of similar materials as the material layer 107, and/or create a pattern similar to the array of holes 113 of FIGS. 6A-6B.

FIG. 8 is a schematic cross-sectional side view illustration of a modified optical element 106M in which the perturbation 108 is a cone-shaped indentation over a micro LED within a defective pixel 102D in accordance with an embodiment. For example, the cone-shaped indentation can be formed by a subtractive technique such as laser (e.g. ultraviolet) patterning, dry etching, embossing, etc.

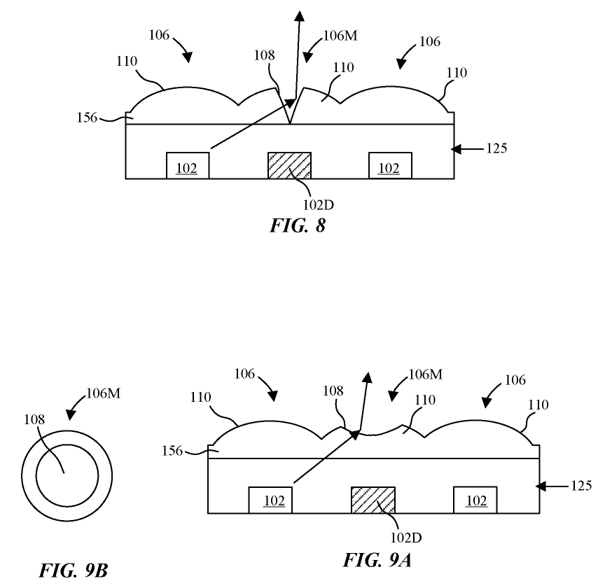

FIG. 9A is a schematic cross-sectional side view illustration of a modified optical element 106M in which the perturbation 108 is an indentation over a micro LED within a defective pixel in accordance with an embodiment. FIG. 9B is a schematic top view illustration of a modified optical element 106M with an indentation in accordance with an embodiment. For example, the indentation of FIGS. 9A-9B can be formed by a subtractive technique such as laser (e.g. ultraviolet) patterning, dry etching, embossing, etc. As shown, the indentation can be characterized by a radius, and form a central cavity when viewed from atop (e.g., FIG. 9B), or arc when viewed from the side.

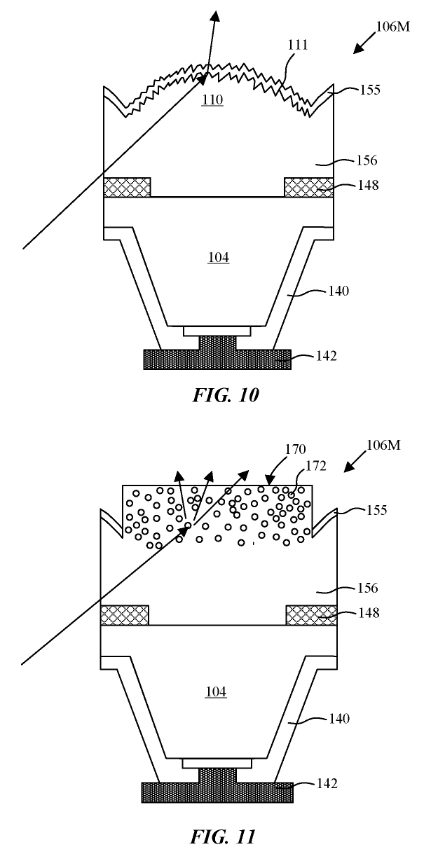

FIG. 10 is a schematic cross-sectional side view illustration of a modified optical element 106M in which the perturbation 108 is a roughened surface over a micro LED 104 within a defective pixel in accordance with an embodiment. In the above discussion, various subtractive and additive methods were described for modifying the optical elements. Generally, the optical elements were described and illustrated as being half-ball lenses 110 formed in the optical layer 156. It is to be appreciated that the optical elements 106 can include multiple layers, such as the optical layer 156 (e.g., silicon nitride) and a capping layer 155 (e.g., silicon dioxide). Silicon nitride may be selected as the optical layer 156 material due to large refractive index, with silicon dioxide selected as the capping layer 155 material to function as an antireflective coating and/or native protection layer. Either layer or both layers may be patterned in accordance with the above embodiments, and either layer can provide the surface onto which an additive layer is formed. As shown, where the optical layer 156 is modified the modified surface profile can also be transferred to the surface profile of the capping layer 155.

FIG. 11 is a schematic cross-sectional side view illustration of a modified optical element 106M in which the perturbation 108 is a diffuser layer 170 over a micro LED 104 within a defective pixel in accordance with an embodiment. In such an embodiment, the optical layer 156 (and optional capping layer 155) can be partially or completely removed over a defective pixel, followed by formation of a diffuser layer 170. The diffuser layer, for example, may include a dispersion 172 of scattering particles or voids to facilitate light scattering.

In utilizing the various aspects of the embodiments, it would become apparent to one skilled in the art that combinations or variations of the above embodiments are possible for modifying an optical element over a defective pixel to facilitate optical crosstalk. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An optoelectronic structure comprising:
an array of pixels;
an array of micro LEDs arranged in the array of pixels, wherein the array of pixels includes a defective pixel; and
an array of optical elements over the array of micro LEDs, wherein the array of optical elements includes a modified optical element including a local perturbation over the defective pixel, and all other optical elements of the array of optical elements have a common shape.

2. The optoelectronic structure of claim 1, wherein the array of optical elements comprises an array of lenses, and the modified optical element includes a modified lens.

3. The optoelectronic structure of claim 2, wherein the local perturbation includes a roughened surface of the modified lens.

4. The optoelectronic structure of claim 2, wherein the local perturbation includes a cone-shaped indentation in the modified lens.

5. The optoelectronic structure of claim 2, wherein the local perturbation includes an indentation, the indentation characterized by a radius.

6. The optoelectronic structure of claim 1, wherein the array of optical elements comprises an array of lenses, and the local perturbation includes a surface layer on top of a lens.

7. The optical structure of claim 1, wherein the array of array of optical elements comprises an array of lenses, and the local perturbation includes a plurality of micro structures on top of a lens.

8. The optoelectronic structure of claim 1, wherein the array of optical elements comprises an array of lenses, and the local perturbation includes a diffuser layer, the diffuser layer including a dispersion of scattering particles or voids.

9. The optoelectronic structure of claim 1, wherein the array of micro LEDs is contained within a coupon that is embedded in a planarization layer.

10. The optoelectronic structure of claim 9, wherein the coupon is connected with a silicon backplane.

11. The optoelectronic structure of claim 9, wherein the array of lenses is a continuous material layer.

12. The optoelectronic structure of claim 11, wherein the continuous material layer spans over the coupon and the planarization layer.

13. The optoelectronic structure of claim 9, further comprising a cover glass spanning over the array of lenses.

14. A method of forming an optical structure comprising:
applying an optically transparent layer over an array of micro LEDs arranged in an array of pixels; and
patterning the optically transparent layer to form an array of optical elements over the array of micro LEDs, the array of optical elements including a local perturbation over a defective pixel.

15. The method of claim 14, wherein patterning the optically transparent layer to form the array of optical elements includes patterning the optically transparent layer to form an array of lenses over the array of micro LEDs, each of the lenses of the array of lenses having a common shape.

16. The method of claim 15, further comprising modifying a lens to include the local perturbation over the defective pixel.

17. The method of claim 16, wherein modifying the lens includes focusing a laser on the lens to roughen a surface of the lens.

18. The method of claim 16, wherein modifying the lens includes forming an indentation in the lens.

19. The method of claim 15, further comprising depositing a surface layer on top of a lens to form the local perturbation.

20. The method of claim 15, further comprising depositing a diffuser layer over the defective pixel to form the local perturbation.

21. The method of claim 15, further comprising:
embedding a coupon in a planarization layer, wherein the array of micro LEDs is contained within the coupon;
wherein applying the optically transparent layer over an array of micro LEDs comprises applying the optically transparent layer over the coupon and the planarization layer.
